(19) United States
(12) Patent Application Publication
(10) Pub. No.: US 2015/0109751 A1
(43) Pub. Date: Apr. 23, 2015

(54) ELECTRONIC DEVICE AND METAL THIN FILM-PROVIDED SPACER

(71) Applicant: Murakami Corporation, Shizuoka (JP)

(72) Inventor: Takuo Mochizuka, Shizuoka (JP)

(73) Assignee: Murakami Corporation, Shizuoka (JP)

(21) Appl. No.: 14/382,986

(22) PCT Filed: Jan. 22, 2013
(86) PCT No.: PCT/JP2013/051134

§ 371 Date: Sep. 4, 2014

(30) Foreign Application Priority Data
Mar. 9, 2012 (JP) 2012-053135

(51) Int. Cl. H05K 1/02; G02F 1/1343; G02F 1/155; G02F 1/1339; H05K 1/14; G02F 1/161

(52) U.S. Cl. CPC H05K 1/0274; H05K 1/142; G02F 1/161; G02F 1/155; G02F 1/1339; G02F 1/1343; H05K 2201/2036; G02F 2001/13398
USPC 361/803

(57) ABSTRACT

Provided is an electronic device such as an electrochromic device or a liquid-crystal device in which a bus bar can be disposed with a simple structure for at least one electrode film and a width of a region that does not provide an intended function of the electronic device can be reduced. An electronic device is formed by integrating two substrates with spacers interposed therebetween, the substrates including respective electrode films on respective surfaces facing each other. At least one of the spacers is formed by a metal thin film-provided spacer obtained by forming a metal thin film on one surface of an insulating plate material. The electrode film of the substrate and the metal thin film of the metal thin film-provided spacer are conductively joined to each other. The electrode film is conductively connected to a terminal connected to an external circuit, via the metal thin film.

### TECHNICAL FIELD

The present invention relates to an electronic device, such as an electrochromic device or a liquid-crystal device, having a structure in which two substrates with respective electrode films formed thereon are disposed facing each other in such a manner that the electrode films face each other, a gap is formed between the two substrates and a functional substance is contained in the gap, the electronic device enabling a bus bar to be disposed with a simple structure for at least one of the electrode films and also enabling reduction of a width of a region that does not provide an intended function of the electronic device. Also, the present invention relates to a metal thin film-provided spacer to be used in the electronic device.

### BACKGROUND ART

FIG. 16 illustrates the electrochromic vehicle mirror illustrated in FIG. 3 of Patent Literature 1. Two transparent substrates 32 and 34 disposed facing each other include respective transparent electrode films 36 and 40 formed on facing surfaces thereof. The transparent substrate 34 includes a reflective film 41 formed on a back surface thereof. A seal 38 is inserted in a peripheral edge of an area between the transparent substrates 32 and 34 and forms a chamber 42 between the transparent substrates 32 and 34. The chamber 42 contains a liquid electrochromic medium. A clip electrode 44 that provides a bus bar conductively connected to the transparent electrode film 36 is attached to a lower side of the transparent substrate 32. A clip electrode 46 that provides a bus bar conductively connected to the transparent electrode film 40 is attached to an upper side of the transparent substrate 34. In order to supply power uniformly to the entire transparent electrode films 36 and 40 with low resistance, the clip electrodes 44 and 46 are attached over substantially entire lengths of the lower side of the transparent substrate 32 and the upper side of the transparent substrate 34, respectively. In such structure in which the clip electrodes 44 and 46 are attached over the entire lengths of the lower side and the upper side of the transparent substrates 32 and 34, respectively as described above, the clip electrodes 44 and 46 impair the design of the mirror and thus a structure in which the clip electrodes 44 and 46 are covered by a housing (bezel) 48 is essential. Also, since the transparent substrates 32 and 34 are disposed offset (shifted) from each other in a vertical direction for attachment of the clip electrodes 44 and 46, a large width D of a region that does not function as a mirror is formed at each of the upper and lower sides of the transparent substrates 32 and 34, resulting in the problem of reduction in effective area of the mirror. Also, since the large width D of the region that does not function as a mirror is formed, a large edge width W of the housing 48 is provided to cover the entire regions by the housing 48, which is also a cause for impairing the design of the mirror.

Patent Literature 2 below discloses an electrochromic device provided focusing on the aforementioned problem of the conventional device, the electrochromic device eliminating the need to attach clip electrodes along outer peripheral edges of substrates. FIG. 17 illustrates the electrochromic device illustrated in FIG. 14 of Patent Literature 2. A transparent substrate 112 with a transparent electrode film 128 formed on one surface thereof and a substrate 114 with an electrode film 120 formed on one surface thereof are disposed facing each other with no offset (that is, not shifted from each other in a surface direction but completely overlapping each other) in such a manner that the electrode films 128 and 120 face each other. A seal 116 is inserted in a peripheral edge of an area between the substrates 112 and 114, whereby a chamber 125 that contains an electrochromic medium 126 is formed. A structural body for disposing a bus bar is housed and disposed at a position outside the seal 116 between the substrates 112 and 114. In other words, the structural body includes conductors (bus bars) 166, which are each formed of a conductor foil, a copper web or any of other highly conductive materials, fixed to both surfaces of an insulating material 164, which is formed of ethylene propylene diene monomer (EPDM), polyester, polyamide or any of other insulating materials, using a PSA (pressure sensitive adhesive). In order to enhance stability of contact between one conductor 166 and the electrode film 128 and contact between the other conductor 166 and the electrode film 120, conductive ink or epoxy 152 is inserted between the conductor 166 and the electrode film 128 and also between the other conductor 166 and the electrode film 120. This structure can eliminate the need for clip electrodes, but has the problem of a region that does not function as a mirror being formed having a large width D1 that is the sum of a width of the seal 116 and a width of the structural body. Also, it is necessary to insert the structural body outside the seal 116 in addition to the seal 116 between the substrates 112 and 114, resulting in complexity of the structure of the members inserted between the substrates 112 and 114.

FIG. 18 illustrates the electrochromic device illustrated in FIG. 22 of Patent Literature 2. This is one in which the conductor (bus bar) 166 conductively connected to one electrode film 120 is formed by a conductive foil or web and disposed so as to extend to the outside of the area between the substrates 112 and 114 in the electrochromic device of FIG. 17. A part of the conductor 166 extending to the outside of the area between the substrates 112 and 114 is wound around the substrate 114 and the part extending outside is connected to an external circuit. The literature describes that the conductor (bus bar) 166 conductively connected to the other electrode film 128 can also be extended to the outside of the area between the substrates 112 and 114.

### CITATION LIST

### Patent Literature

Patent Literature 1: U.S. Pat. No. 6,102,546 (FIG. 3)
Patent Literature 2: Japanese Patent Laid-Open No. 2011-103005 (FIGS. 14 and 22)

### SUMMARY OF INVENTION

### Technical Problem

In the structure in FIG. 18, a width D1 that is the sum of the width of the seal 116 and the width of the structural body for disposition of the bus bars 166 and 166 still provides a region that does not function as a mirror, and thus, there is the problem of a region that does not function as a mirror having a large width D1. Also, the complex structure in which in addition to the seal 116, the structural body is inserted outside the seal 116 between the substrates 112 and 114 is provided.

The present invention is intended to provide an electronic device that solves the above problems in the conventional devices, and enables a bus bar to be disposed with a simple structure for at least one electrode film and also enables reduction in width of a region that does not provide an intended function of the electronic device. Also, the present invention is intended to provide a metal thin film-provided spacer to be used in the electronic device.

### Solution to Problem

An electronic device according to the present invention is an electronic device comprising: first and second substrates disposed facing each other; first and second electrode films formed on facing surfaces of the first and second substrates, respectively; first and second terminals disposed so as to be exposed outside of an area between the first and second substrates in order to each connect the first and second electrode films with an external circuit disposed outside of the area between the first and second substrates; a spacer inserted in a peripheral edge of the area between the facing surfaces of the first and second substrates and joined between the facing surfaces, an inner peripheral side of the inserted spacer forming a chamber between the facing surfaces of the first and second substrates; and a functional substance contained in the chamber, wherein the spacer includes a first metal thin film-provided spacer having a part being disposed along at least a partial region of an entire length of the peripheral edge between the first and second substrates, the part of the first metal thin film-provided spacer has a first metal thin film formed on at least one surface of an insulating plate material; wherein the surface of the first substrate with the first electrode film formed thereon and the surface of the first metal thin film-provided spacer with the first metal thin film formed thereon are conductively joined to each other, whereby the first metal thin film is conductively connected to the first electrode film and is not conductively connected to the second electrode film; and wherein the first electrode film is conductively connected to the first terminal via the first metal thin film.

In the electronic device according to the present invention, the first metal thin film-provided spacer provides a seal and the first metal thin film formed on the spacer provides a bus bar for the first electrode film. Therefore, the bus bar provided by the first metal thin film is disposed within a width of the seal, and thus, in comparison to cases where areas for widths of bus bars are needed in addition to that for a width of a seal in surfaces of substrates like the conventional devices illustrated in FIGS. 16 and 17, the width of the region that does not provide an intended function of the electronic device (for example, a function that changes the transmittance if the electronic device is an electrochromic device or a liquid-crystal device) can be reduced. Also, the insulating plate material of the metal thin film-provided spacer doubles as a support member for the bus bar, enabling the bus bar to be disposed with a simple structure.

In the electronic device according to the present invention, it is possible that: the first metal thin film-provided spacer includes a first projection projecting outside of the area between the facing surfaces of the first and second substrates from a position in a part in an extension direction of the first metal thin film-provided spacer; and thereby a part of the first metal thin film formed on the first projection provides the first terminal. Consequently, the first terminal can easily be formed.

In the electronic device according to the present invention, a bus bar for the second electrode film can be formed in various manners. For example, as a first configuration, it is possible that the second substrate includes a region projecting outward relative to the first substrate on an opposite side of a region in which the first metal thin film-provided spacer is disposed in the entire length of the peripheral edge between the first and second substrates, and a part of the second electrode film formed on the region of the second substrate, the region projecting outward, provides the second terminal. In this case, the bus bar can be formed by, for example, a clip electrode attached along the second terminal.

Also, as a second configuration, it is possible that: the spacer includes a second metal thin film-provided spacer having a part being disposed in a region on an opposite side of the region in which the first metal thin film-provided spacer is disposed in the entire length of the peripheral edge between the first and second substrates, the part of the second metal thin film-provided spacer has a second metal thin film formed on one surface of an insulating plate material; the surface of the second substrate with the second electrode film formed thereon and the surface of the second metal thin film-provided spacer with the second metal thin film formed thereon are conductively joined to each other, whereby the second metal thin film is conductively connected to the second electrode film and not conductively connected to the first electrode film; and the second electrode film is conductively connected to the second terminal via the second metal thin film. In this case, the second metal thin film provides a bus bar for the second electrode film. In this case, it is possible that: the second metal thin film-provided spacer includes a second projection projecting outside of the area between the facing surfaces of the first and second substrates from a position in a part in an extension direction of the second metal thin film-provided spacer; and a part of the second metal thin film formed on the second projection provides the second terminal. Consequently, the second terminal can easily be formed.

Also, as a third configuration, it is possible that: the first metal thin film-provided spacer includes a second metal thin film formed on a back surface of the insulating plate material; the surface of the second substrate with the second electrode film formed thereon and the surface of the first metal thin film-provided spacer with the second metal thin film formed thereon are conductively joined to each other, whereby the second metal thin film is conductively connected to the second electrode film and is not conductively connected to the first electrode film; and the second electrode film is conductively connected to the second terminal via the second metal thin film. In this case, the second metal thin film provides a bus bar for the second electrode film. In this case, it is possible that: the first metal thin film-provided spacer includes a first projection projecting outside of the area between the facing surfaces of the first and second substrates from a position in a part in an extension direction of the first metal thin film-provided spacer; a part of the first metal thin film formed on the first projection provides the first terminal; and a part of the second metal thin film formed on the first projection provides the second terminal.

Also, as a fourth configuration, it is possible that: the first metal thin film-provided spacer includes a first projection projecting outside of the area between the facing surfaces of the first and second substrates from a position in a part in an extension direction of the first metal thin film-provided spacer, and a second projection projecting outside of the area between the facing surfaces of the first and second substrates from a position in another part in the extension direction of the first metal thin film-provided spacer; a part of the first metal thin film formed on the first projection provides the first terminal; and a part of the second metal thin film formed on the second projection provides the second terminal. In this case, the second metal thin film provides a bus bar for the second electrode film.

In the electronic device according to the present invention, it is possible that the insulating substrate of each of the metal thin film-provided spacer(s) is formed of a material such as, for example, a glass plate, a ceramic plate or a plastic plate. Also, it is possible that the insulating substrate of each of the metal thin film-provided spacer(s) has a thickness of, for example, no less than 0.2 mm (which is, however, less than a thickness that makes a distance between the first and second electrode films be a distance that makes it impossible to provide an intended function as an electronic device). Consequently, a sufficient distance between a metal thin film of a metal thin film-provided spacer and an electrode film that should not be conductively connected to the metal thin film can be ensured, enabling the metal thin film and the electrode film to be, for example, short-circuited via, e.g., a run-off part of a conductive adhesive. Also, it is possible that each of the metal thin film(s) is formed of a metal material, for example, such as Cr, Al, Ag or Ni. Also, where the substrates each have a surface shape having a long direction and a short direction (for example, a rectangular shape), it is possible that each of the metal thin film-provided spacer(s) is disposed on, for example, a side along long directions of the substrates. Also, it is possible that, for example, a clip electrode is attached to each of the projection(s) so as to pinch the projection and a lead wire is connected to the clip electrode, whereby the lead wire is conductively connected to the electrode film formed on the projection via the clip electrode. Also, it is possible that an outer peripheral edge of each of the metal thin film-provided spacer(s) is disposed so as to overlap an outer peripheral edge of each of the substrates. Consequently, a width of a region that does not provide an intended function of the electronic device can further be reduced. Also, it is possible that the surfaces of the substrates with the respective electrode films formed thereon and the surface(s) of the metal thin film-provided spacer(s) with the respective metal thin film(s) formed thereon are conductively joined to each other, for example, via bonding using a conductive adhesive. Also, it is possible that surfaces of the spacer other than the surface(s) subjected to the bonding using the conductive adhesive are joined to the first and second substrates, for example, via bonding using an insulating adhesive. Also, in the electronic device according to the present invention, for example, it is possible that: at least one of the first and second substrates is a transparent substrate; at least an electrode film formed on the transparent substrate from among the first and second electrode films is a transparent electrode film; and the functional substance is a fluid substance, such as an electrochromic electrolyte or liquid crystal, having an optical characteristic that varies depending on a voltage or a current supplied between the first and second electrode films.

A metal thin film-provided spacer according to the present invention is a metal thin film-provided spacer to be used as the spacer in an electronic device, the electronic device including first and second substrates disposed facing each other, first and second electrode films formed on facing surfaces of the first and second substrates, respectively, the spacer inserted in a peripheral edge of an area between the facing surfaces of the first and second substrates and joined between the facing surfaces, an inner peripheral side of the inserted spacer forming a chamber between the facing surfaces of the first and second substrates, and a functional substance contained in the chamber, wherein the metal thin film-provided spacer has a structure in which a metal thin film is formed on at least one surface of an insulating plate material.

### BRIEF DESCRIPTION OF DRAWINGS

FIG. 1 is a front view illustrating Embodiment 1 of an electronic device according to the present invention.

FIG. 2 is an exploded perspective view of the electronic device in FIG. 1.

FIG. 3 is a schematic cross-sectional view on arrow A-A in FIG. 1.

FIG. 4 is a schematic cross-sectional view on arrow B-B in FIG. 1.

FIG. 5 is a diagram illustrating an example practical use of the electronic device in FIG. 1, and is a diagram of such electronic devices formed as electrochromic vehicle sun visor devices and disposed on an upper portion of a front windshield of a vehicle, as viewed from the rear side of the vehicle interior.

FIG. 6 is a diagram illustrating Embodiment 2 of an electronic device according to the present invention, which is a front view of an electrochromic vehicle inner mirror to which the present invention has been applied.

FIG. 7 is an exploded perspective view of the electrochromic vehicle inner mirror in FIG. 6.

FIG. 8 is a schematic cross-sectional view on arrow C-C in FIG. 6.

FIG. 9 is a diagram illustrating Embodiment 3 of an electronic device of the present invention, which is a front view of an electrochromic vehicle inner mirror to which the present invention has been applied.

FIG. 10 is an exploded perspective view of the electrochromic vehicle inner mirror in FIG. 9.

FIG. 11 is a schematic cross-sectional view on arrow D-D in FIG. 9 (a schematic cross-sectional view on arrow G-G in FIG. 13 is the same as FIG. 11).

FIG. 12 includes an enlarged view and schematic cross-sectional (sectional end) views of a projection 214a′ in FIG. 9.

FIG. 13 is a diagram illustrating Embodiment 4 of an electronic device according to the present invention, which is a front view of an electrochromic vehicle inner mirror to which the present invention has been applied.

FIG. 14 is an exploded perspective view of the electrochromic vehicle inner mirror in FIG. 13.

FIG. 15 is a schematic bottom view of the electrochromic vehicle inner mirror in FIG. 13.

FIG. 16 is a cross-sectional view of the conventional electrochromic vehicle mirror illustrated in FIG. 3 of Patent Literature 1.

FIG. 17 is a cross-sectional view of an electrochromic device illustrated in FIG. 14 of Patent Literature 2.

FIG. 18 is a cross-sectional view of an electrochromic device illustrated in FIG. 22 of Patent Literature 2.

### DESCRIPTION OF EMBODIMENTS

### Embodiment 1

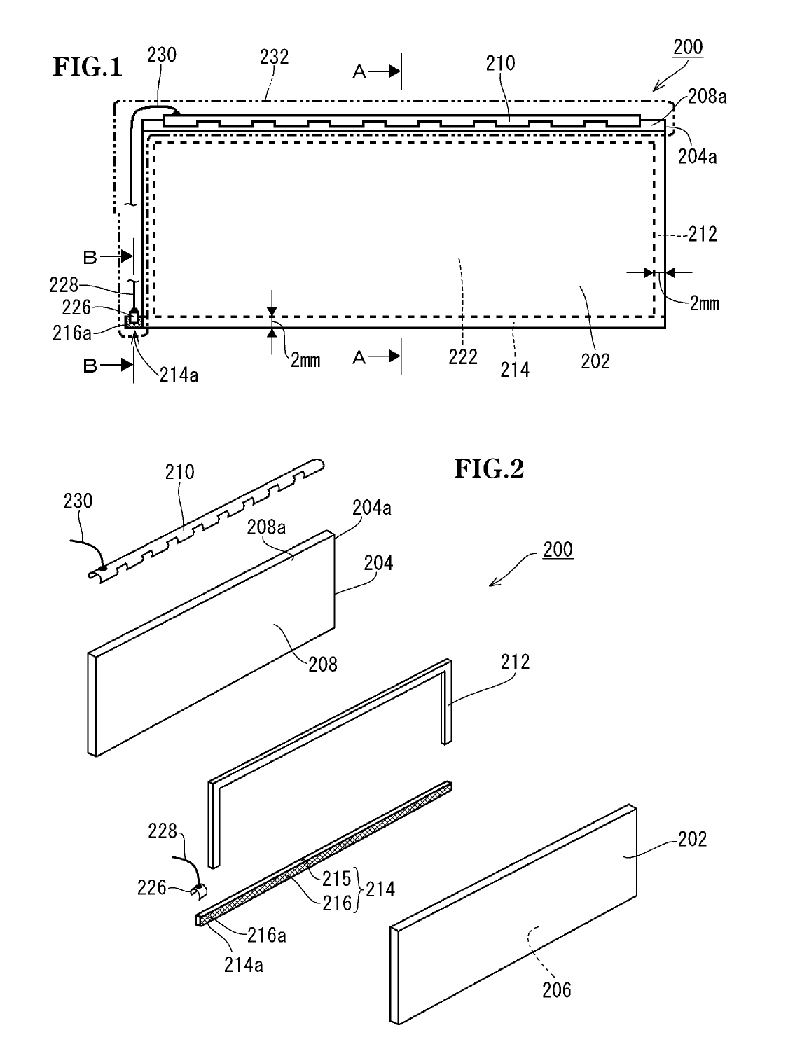

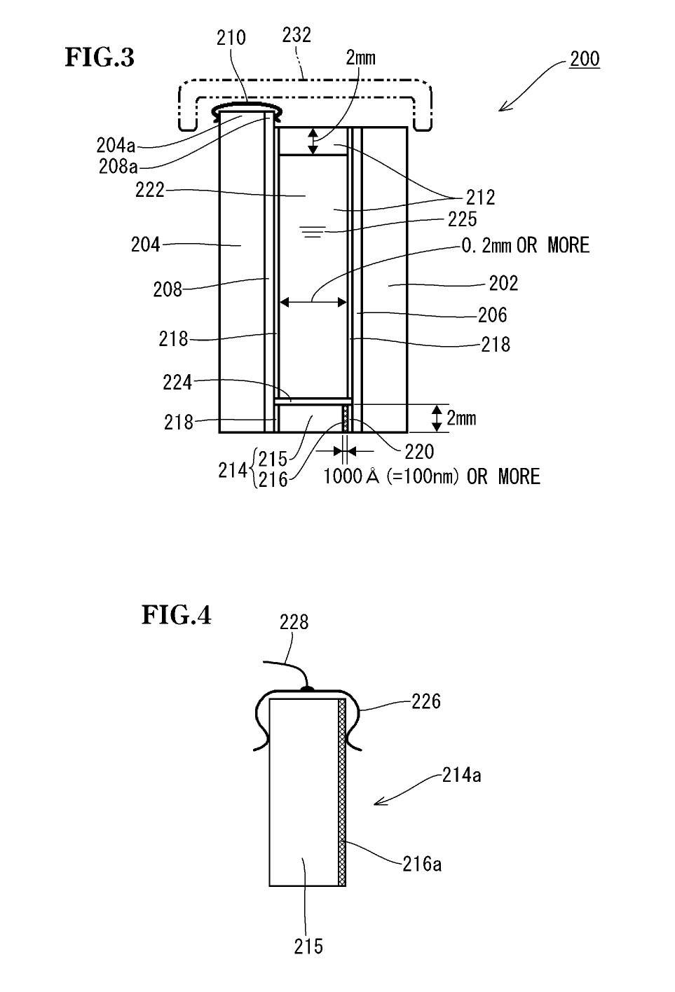

FIGS. 1 to 4 illustrate Embodiment 1 of an electronic device according to the present invention. In this embodiment, an electronic device according to the present invention is configured as a transmissive element. The transmissive element can be used as, for example, an electrochromic or liquid-crystal building dimming window, an electrochromic vehicle dimming window, electrochromic dimming glasses or an electrochromic vehicle sun visor device, which is described later as an example application. Here, a bus bar is formed using a metal thin film-provided spacer according to the present invention for one of respective electrode films formed on two substrates, and a bus bar is formed using a conventional clip electrode for the other electrode film. As illustrated in the front view in FIG. 1, an electronic device 200 has a front shape of a horizontally-long rectangle. As illustrated in the exploded perspective view in FIG. 2, the electronic device 200 includes a front-side transparent substrate 202 and a rear-side transparent substrate 204 disposed facing each other. Lengths in a long direction of the transparent substrates 202 and 204 are the same, but a length in a short direction (height) of the rear-side transparent substrate 204 is a little larger (higher) than that of the transparent substrate 202 by the amount of attachment of a clip electrode 210 to an upper side of the rear-side transparent substrate 204 (see FIG. 3). Transparent electrode films 206 and 208 of, e.g., ITO (tin-doped indium oxide) are formed on entire facing surfaces of the transparent substrates 202 and 204, respectively, using a film-forming technique such as sputtering or vapor deposition.

Spacers 212 and 214 are inserted in a peripheral edge of an area between the facing surfaces of the transparent substrates 202 and 204. The spacer 212 is formed of an insulating plate material having stiffness, such as a glass sheet, a ceramic sheet or a plastic sheet, (which does not have to be transparent) and having a front shape of a squared “U”, which is disposed on three sides, an upper side, a left side and a right side, of each of the transparent substrates 202 and 204. The spacer 214 is formed as a metal thin film-provided spacer by forming a metal thin film 216 of, e.g., Cr, Al, Ag or Ni on an entire front surface (surface facing the transparent substrate 202) of an insulating plate material 215 having stiffness, such as a glass sheet, a ceramic sheet or a plastic sheet, (which does not have to be transparent) using a film-forming technique such as sputtering or vapor deposition, and is disposed on the lower sides of the transparent substrates 202 and 204. The spacers 212 and 214 each have a length in the short direction (width) of, for example, 2 mm and a thickness that is, for example, no less than 0.2 mm and is less than a thickness that makes a distance between the transparent electrode films 206 and 208 be a distance that makes it impossible to provide an intended function of the electronic device 200 (see FIG. 3). A thickness of the metal thin film 216 is a thickness that provides a resistance value that is sufficiently low for the metal thin film 216 to function as a bus bar for the transparent electrode film 206, and is set to, for example, no less than 1000 angstrom (=100 nm).

As illustrated in FIG. 3, both surfaces of the spacer 212 are bonded to the transparent substrates 202 and 204 via an insulating adhesive 218. A back surface of the spacer 214 is bonded to the transparent substrate 204 via an insulating adhesive 218 and a front surface of the spacer 214 is bonded to the transparent substrate 202 via a conductive adhesive 220. Consequently, the transparent substrates 202 and 204 are integrated with the spacers 212 and 214 interposed therebetween. Here, the left sides, the right sides and the lower sides of the transparent substrates 202 and 204 overlap each other without misalignment, and the upper side of the transparent substrate 204 slightly project relative to the upper side of the transparent substrate 202 by the amount of the dimension of the upper side of the transparent substrate 204 that is larger than that of the transparent substrate 202. A part 208a of the transparent electrode film 208 formed on the projecting upper side 204a of the transparent substrate 204 provides a terminal disposed so as to be exposed outside of the area between the transparent substrates 202 and 204 in order to connect the transparent electrode film 208 to an external circuit. In a state in which the transparent substrates 202 and 204 are integrated, the transparent electrode film 206 of the transparent substrate 202 and the metal thin film 216 of the spacer 214 are conductively connected via the conductive adhesive 220. As described above, as a result of the thickness of the spacer 214 being set to no less than 0.2 mm, when the metal thin film 216 is bonded to the transparent electrode film 206 using the conductive adhesive 220, even if a part of the conductive adhesive 220 slightly runs off to the outside of the spacer 214, the run-off part hardly reaches the transparent electrode film 208 on the opposite side, preventing the transparent electrode films 206 and 208 from being short-circuited through the run-off part. Also, in the integrated state, a chamber 222 is formed on the inner peripheral side surrounded by the spacers 212 and 214 between the transparent substrates 202 and 204. The chamber 222 is filled with a functional substance 225 having fluidity from, for example, a gap 224 (FIG. 3) between the spacers 212 and 214. The functional substance 225 is an electrochromic electrolyte if the electronic device 200 is an electrochromic device, and is a liquid crystal if the electronic device 200 is a liquid-crystal device. The gap 224 is sealed by, e.g., an adhesive after the filling of the functional substance 225, whereby the chamber 222 is shut off from external air.

As illustrated in FIG. 1, the spacer 214 is formed to be longer in a long direction than the transparent substrates 202 and 204, whereby an end of the spacer 214 projects outside from the area between the facing surfaces of the transparent substrates 202 and 204 and thereby forms a projection 214a. A part 216a of the metal thin film 216 formed on the projection 214a provides a terminal disposed so as to be exposed outside of the area between the transparent substrates 202 and 204 in order to connect the transparent electrode film 206 to the external circuit. An outer peripheral edge of each of the spacers 212 and 214 overlaps an outer peripheral edge of the transparent substrate 202 except a position of the projection 214a. A short clip electrode 226 is attached to the projection 214a so as to pinch the projection 214a. The clip electrode 226 is conductively connected to the part 216a of the metal thin film 216 formed on the projection 214a (FIG. 4). Consequently, the clip electrode 226 is conductively connected to the transparent electrode film 206 via the metal thin film 216 and the conductive adhesive 220 from the terminal 216a. A lead wire 228 is connected to the clip electrode 226.

A band-like, long clip electrode 210 (similar to the conventional clip electrodes 44 and 46 illustrated in FIG. 16) is attached to the upper side 204a of the transparent substrate 204 so as to pinch the upper side 204a. Consequently, the clip electrode 210 is conductively connected to the transparent electrode film 208 via the terminal 208a. A lead wire 230 is connected to the clip electrode 210. The lead wires 228 and 230 are connected between positive and negative electrodes of a direct-current power supply in the external circuit (not illustrated except the lead wires 228 and 230), whereby a voltage is applied between the transparent electrode films 206 and 208. Consequently, if the electronic device 200 is an electrochromic device or a liquid-crystal device, a transmittance of light passing through the substrates 202 and 204 changes, providing, for example, a dimming function. As illustrated in FIG. 1, as necessary, a cover 232 covering the clip electrodes 210 and 226 is attached to a part from an upper side to a left side of the electronic device 200.

The electronic device 200 having the above-described configuration enables elimination of a clip electrode attached to the lower side of the transparent substrate 202 (the clip electrode 44 of the conventional device in FIG. 16). Furthermore, the spacer 214 serves as both a seal of the chamber 222 and a function as a bus bar for the transparent electrode film 206 by means of the metal thin film 216, within the width thereof (2 mm in the example in FIG. 1), enabling reduction in width of a region that does not provide an intended function of the electronic device (for example, a function that changes the transmittance if the electronic device is an electrochromic device or a liquid-crystal device). Also, the insulating plate material 215 of the spacer 214 doubles as a support member for the metal thin film 216 that serves as a bus bar, enabling the bus bar to be disposed with a simple structure. Also, the terminal 216a of the transparent electrode film 206 can easily be formed by the projection 214a of the spacer 214.

### <Example Application of Embodiment 1>

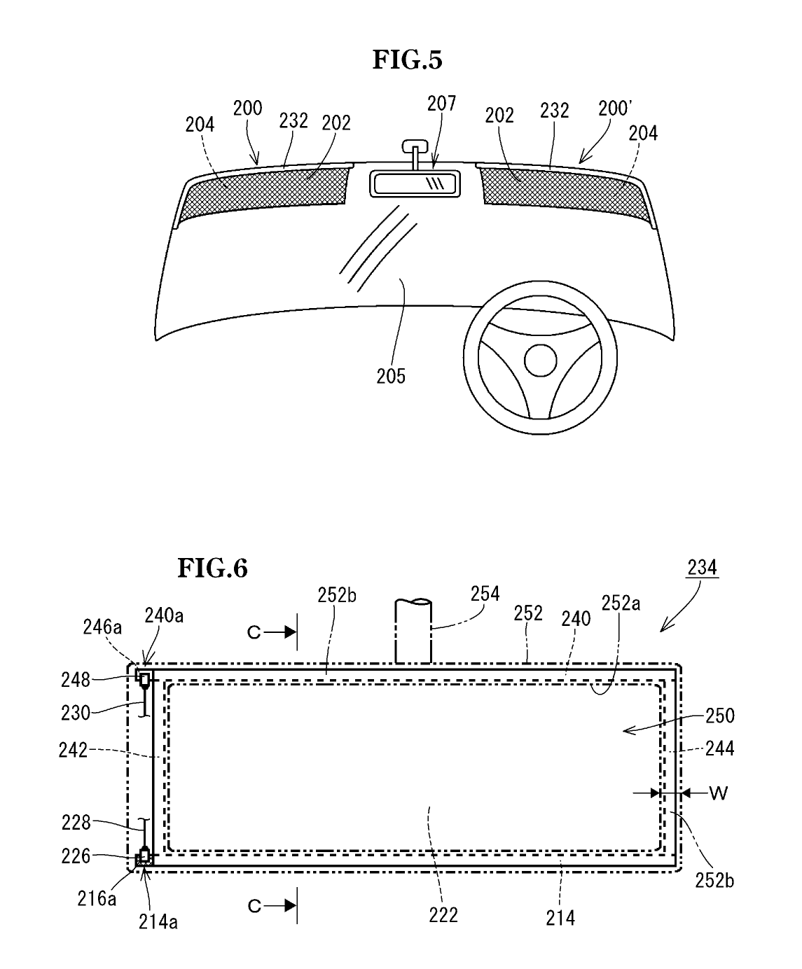

FIG. 5 illustrates an example application in which the electronic device 200 in FIG. 1 is configured as an electrochromic vehicle sun visor device. A sun visor device obtained by forming an electrochromic device 200 having the structure in FIG. 1 so as to have a shape curved along a surface of a front windshield 205 of a vehicle is fixedly attached to the front passenger seat side of an upper portion on the interior side of the front windshield 205. Also, a sun visor device obtained by forming an electrochromic device 200′ having a structure symmetrical to the electrochromic device 200 on the front passenger seat side so as to have a shape curved along the surface of the front windshield 205 is fixedly attached to the driver seat side on the upper portion on the interior side of the front windshield 205 of the vehicle. A cover 232 of the sun visor device 200 on the front passenger seat side is attached to parts from upper sides to left sides of substrates 202 and 204 so as to cover clip electrodes 210 and 226 (FIG. 1). Since no cover is attached to parts from right sides to lower sides of the substrates 202 and 204, a field of front vision is not hindered by the cover. A cover 232 of the sun visor device 200′ on the driver seat side is also attached to parts from upper sides to right sides of the substrates 202 and 204 so as to cover clip electrodes 210 and 226 (the clip electrode 226 is disposed on the right side). Since no cover is attached to parts from left sides to lower sides of the substrates 202 and 204, a field of front vision is not hindered by the cover.

The sun visor devices 200 and 200′ are respectively driven by turning on/off respective switches (not illustrated) individually provided on the front passenger seat side and the driver seat side. In other words, in normal time, the switches are in an off state. Then, in each of the sun visor devices 200 and 200′, no voltage applied between both electrodes and a high transmittance is held. On the other hand, if the glare of sunlight comes from the front side of the vehicle, the switches are turned on. Then, a voltage is applied between both electrodes of each of the sun visor devices 200 and 200′, and the respective transmittances are thereby lowered to reduce the glare of the sunlight.

### Embodiment 2

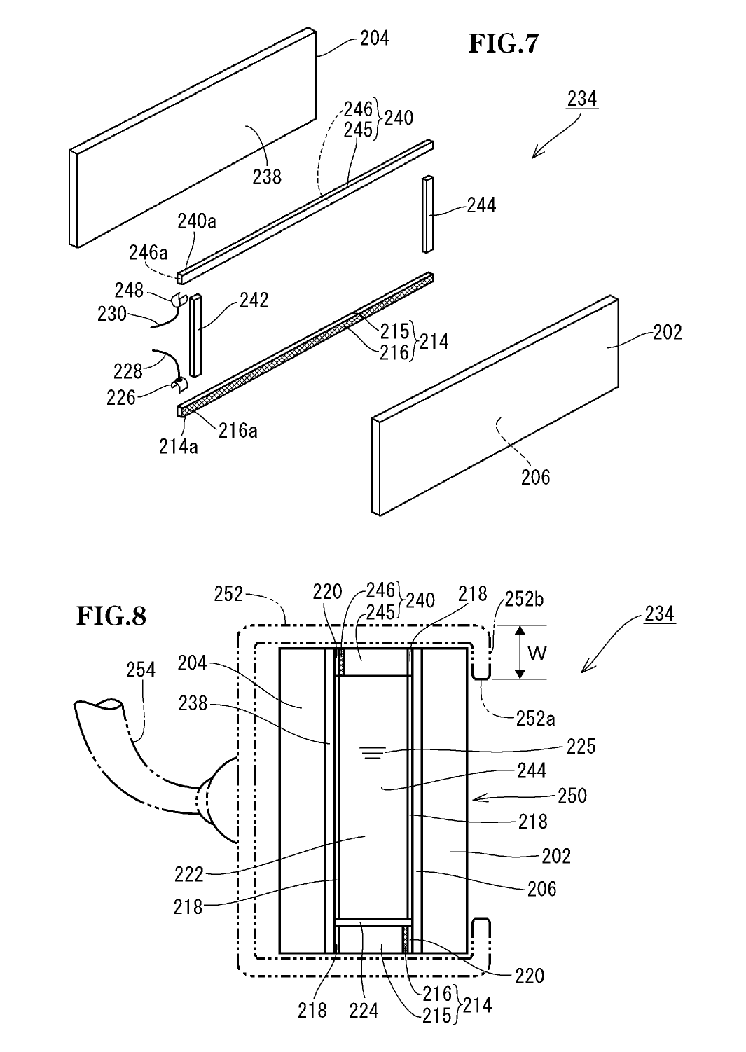

FIGS. 6 to 8 illustrate Embodiment 2 of the present invention. In this embodiment, an electronic device according to the present invention is configured as an electrochromic vehicle inner mirror. Here, bus bars are formed for respective electrode films formed on two substrates, using (two) separate metal thin film-provided spacers according to the present invention. For parts corresponding to those of Embodiment 1, reference numerals that are the same as those of Embodiment 1 are used. In an inner mirror 234, substrates 202 and 204 have same dimensions in a long direction and a short direction. While the substrate 202 is transparent, the substrate 204 does not have to be transparent. From among facing surfaces of the substrates 202 and 204, on the transparent substrate 202 side, a transparent electrode film 206 is formed using a film forming technique such as sputtering or vapor deposition, and on the substrate 204 side, an electrode and reflection film 238 of a metal thin film of, e.g., Cr, Al, Ag or Ni is formed using a film forming technique such as sputtering or vapor deposition.

Spacers 214, 240, 242 and 244 are inserted in a peripheral edge of an area between the facing surfaces of the substrates 202 and 204. The spacer 214 is one that is the same as the spacer 214 in Embodiment 1, and is configured as a metal thin film-provided spacer by forming a metal thin film 216 of, e.g., Cr, Al, Ag or Ni on an entire front surface of an insulating plate material 215 having stiffness, such as a glass sheet, a ceramic sheet or a plastic sheet, using a film forming technique such as sputtering or vapor deposition, and is disposed on respective lower sides of the substrates 202 and 204. The spacer 240 is one obtained by reversing the front and the back of the spacer 214, and is configured as a metal thin film-provided spacer by forming a metal thin film 246 on an entire back surface of an insulating plate material 245 using a film forming technique such as sputtering or vapor deposition, and is disposed on respective upper sides of the substrates 202 and 204. The spacers 242 and 244 are each formed by an insulating plate material having stiffness such as a glass sheet, a ceramic sheet or a plastic sheet, and are disposed on left sides and right sides of the substrates 202 and 204, respectively. The spacers 214, 240, 242 and 244 each have a length in the short direction (width) of, for example, 2 mm and a thickness that is, for example, no less than 0.2 mm and is less than a thickness that makes a distance between the electrode films 206 and 238 be a distance that makes it impossible to provide an intended function as an electrochromic element. A thickness of each of the metal thin films 216 and 246 is a thickness that provides a resistance value that is sufficiently low for the metal thin film 216 or 246 to function as a bus bar for the electrode film 206 or 238, and is set to, for example, no less than 1000 angstrom (=100 nm).

As illustrated in FIG. 8, both surfaces of each of the spacers 242 and 244 are bonded to the respective substrates 202 and 204 via an insulating adhesive 218. A back surface of the spacer 214 is bonded to the substrate 204 via an insulating adhesive 218, and a front surface of the spacer 214 is bonded to the substrate 202 via a conductive adhesive 220. A front surface of the spacer 240 is bonded to the substrate 202 via an insulating adhesive 218, and a back surface of the spacer 240 is bonded to the substrate 204 via a conductive adhesive 220. Consequently, the substrates 202 and 204 are integrated with the spacers 214, 240, 242 and 244 interposed therebetween. Here, the substrates 202 and 204 overlap each other without misalignment. In a state in which the substrates 202 and 204 are integrated, the electrode film 206 of the substrate 202 and the metal thin film 216 of the spacer 214 are conductively connected via the conductive adhesive 220. Also, the electrode and reflection film 238 of the substrate 204 and the metal thin film 246 of the spacer 240 are conductively connected via the conductive adhesive 220. Also, in the integrated state, a chamber 222 is formed on the inner peripheral side surrounded by the spacers 214, 240, 242 and 244 between the substrates 202 and 204. The chamber 222 is filled with a liquid electrochromic electrolyte 225 from, for example, a gap 224 between the spacers 214 and 244. The gap 224 is sealed by, e.g., an adhesive after the filling of the electrochromic electrolyte 225, whereby the chamber 222 is shut off from external air.

As illustrated in FIG. 6, the spacers 214 and 240 are each formed to be longer in the long direction than the substrates 202 and 204, whereby an end of each of the spacers 214 and 240 projects outside from the area between the facing surfaces of the substrates 202 and 204 and thereby forms a projection 214a or 240a. A part 216a of the metal thin film 216 formed on the projection 214a provides a terminal disposed so as to be exposed outside of the area between the substrates 202 and 204 in order to connect the electrode film 206 to an external circuit. A part 246a of the metal thin film 246 formed on the projection 240a provides a terminal disposed so as to be exposed outside of the area between the substrates 202 and 204 in order to connect the electrode film 238 to the external circuit. An outer peripheral edge of each of the spacers 214, 240, 242 and 244 overlap outer peripheral edges of the substrates 202 and 204 except positions of the projections 214a and 240a. Short clip electrodes 226 and 248 are attached to the respective projections 214a and 240a so as to pinch the projections 214a and 240a. The clip electrodes 226 and 248 are conductively connected to the respective parts 216a and 246a of the metal thin films 216 and 246, which are formed on the respective projections 214a and 240a. Consequently, the clip electrode 226 is conductively connected to the electrode film 206 via the metal thin film 216 and the conductive adhesive 220 from the terminal 216a. Also, the clip electrode 248 is conductively connected to the electrode and reflection film 238 via the metal thin film 246 and the conductive adhesive 220 from the terminal 246a. Lead wires 228 and 230 are connected to the respective clip electrodes 226 and 248. The lead wires 228 and 230 are connected between positive and negative electrodes of a direct-current power supply in the external circuit (not illustrated except the lead wires 228 and 230). Upon a switch of the external circuit being turned on to supply a direct-current voltage between the lead wires 228 and 230, the voltage is applied between the electrode films 206 and 238 and the electrochromic electrolyte 225 in the chamber 222 is colored and a reflectance of the electrode and reflection film 238 through the electrochromic electrolyte 225 is thereby lowered, providing an anti-glare state. Also, upon the switch being turned off to short-circuit the lead wires 228 and 230, the electrochromic electrolyte 225 in the chamber 222 is decolored and the reflectance of the electrode and reflection film 238 through the electrochromic electrolyte 225 is thereby raised, providing a non-anti-glare state.

As illustrated in FIGS. 6 and 8, a mirror body 250 (structural object obtained by integrating the substrates 202 and 204 with the spacers 214, 240, 242 and 244 interposed therebetween) is housed and held inside a housing (cover) 252. A lower end of a stay 254 is tiltably joined to a back surface of the housing 252. An upper end of the stay 254 is fixed to a ceiling of a front portion of the interior of the vehicle. Consequently, the inner mirror 234 is hung from the ceiling of the front portion of the interior of the vehicle via the stay 254 in such a manner that is similar to the inner mirror 207 illustrated in FIG. 5.

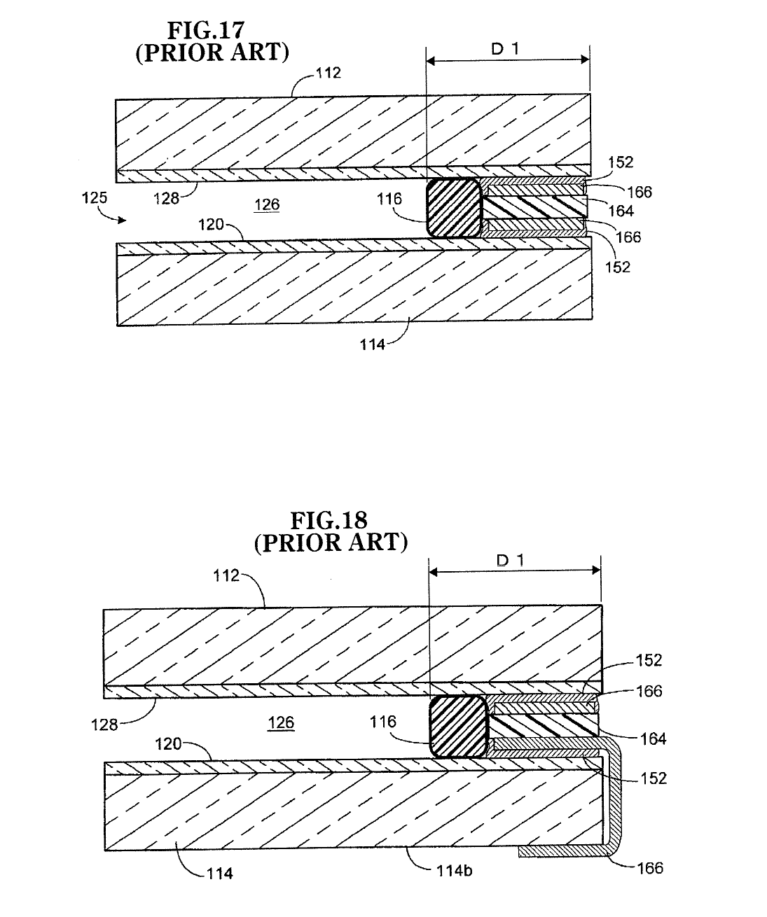

As illustrated in FIGS. 6 and 8, an opening 252a that exposes a reflective surface of the inner mirror 234 is formed in a front surface of the housing 252. An edge width W of a front-surface edge 252b of the housing 252 is large at a left side for covering the projections 214a and 240a, the clip electrodes 226 and 248 and the lead wires 228 and 230 in addition to the spacer 242, but can be made small at each of an upper side, a lower side and a right side because the width W at each of the upper side, the lower side and the right side only needs to have a size enough to cover the spacers 240, 214 and 244. Therefore, the edge width W can be made smaller, in particular, at the upper side and the lower side, compared to that of the conventional device illustrated in FIG. 16 in which in addition to the seal 38, the clip electrodes 44 and 46 are disposed outside the seal 38 as bus bars for the transparent electrode films 36 and 40, and compared to those of the conventional devices illustrated in FIGS. 17 and 18 in which in addition to the seal 116, a structural body for disposing the bus bars 166 and 166 for the electrode films 128 and 120 is inserted outside the seal 116.

### Embodiment 3

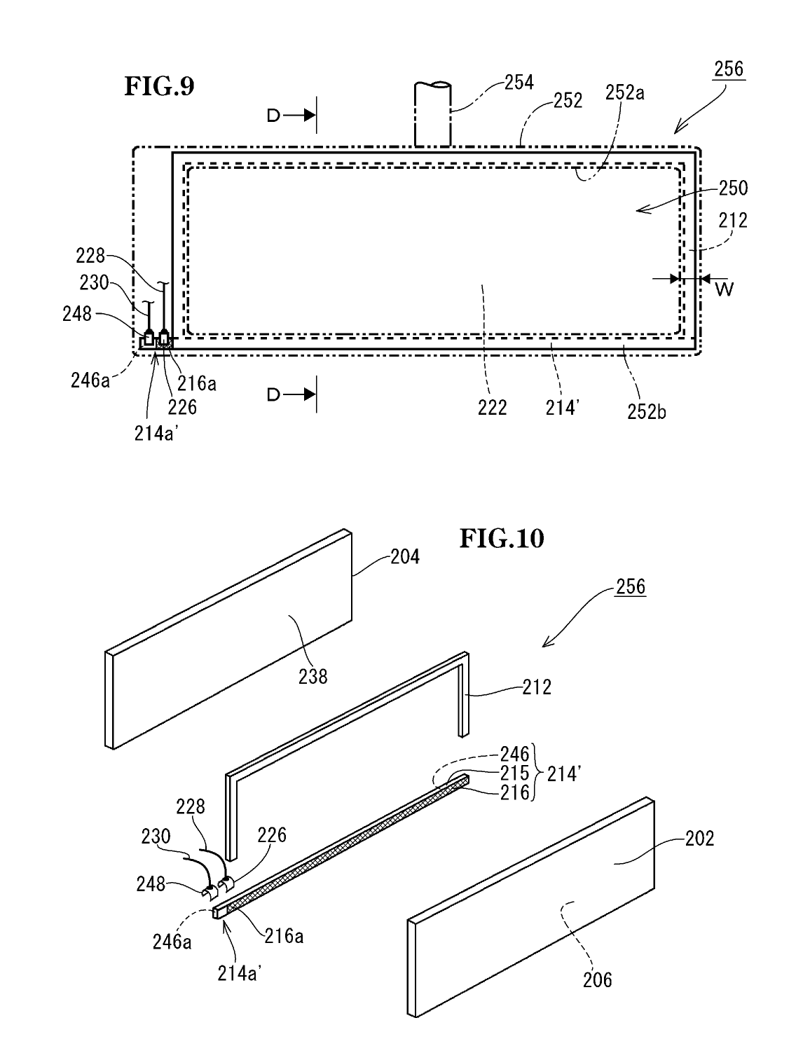

FIGS. 9 to 12 illustrate Embodiment 3 of the present invention. In this embodiment, an electronic device according to the present invention is configured as an electrochromic vehicle inner mirror. Here, bus bars are formed for respective electrode films of two substrates, using a common (single) metal thin film-provided spacer according to the present invention. In other words, metal thin films 216 and 246 are formed on both surfaces, i.e., a front surface and a back surface, of a metal thin film-provided spacer 214′ disposed at a lower side of an inner mirror 256 so as to be not conductively connected to each other. For parts corresponding to those of Embodiments 1 and 2, reference numerals that are the same as those of Embodiments 1 and 2 are used. In the inner mirror 256, substrates 202 and 204 have same dimensions in a long direction and a short direction. While the substrate 202 is transparent, the substrate 204 does not have to be transparent. From among facing surfaces of the substrates 202 and 204, on the transparent substrate 202 side, a transparent electrode film 206 is formed using a film forming technique such as sputtering or vapor deposition, and on the substrate 204 side, an electrode and reflection film 238 of a metal thin film of, e.g., Cr, Al, Ag or Ni is formed using a film forming technique such as sputtering or vapor deposition.

Spacers 212 and 214′ are inserted in a peripheral edge of an area between the facing surfaces of the substrates 202 and 204. The spacer 212 is formed of an insulating plate material having stiffness, such as a glass sheet, a ceramic sheet or a plastic sheet, (which does not have to be transparent) and having a front shape of a squared “U”, which is disposed on three sides, an upper side, a left side and a right side, of each of the substrates 202 and 204. The spacer 214′ is somewhat longer than the spacer 214 of Embodiment 2, and is configured by forming a metal thin film 216 of, e.g., Cr, Al, Ag or Ni on an entire front surface except a region at a left end of the insulating plate material 215 having stiffness such as a glass sheet, a ceramic sheet or a plastic sheet using a film forming technique such as sputtering or vapor deposition and forming a metal thin film 246 of, e.g., Cr, Al, Ag or Ni on an entire surface except a region immediately adjacent to a left end of a back surface of the insulating plate material 215 using a film forming technique such as sputtering or vapor deposition, and is disposed on the lower sides of the substrates 202 and 204. The spacers 212 and 214′ each have a length in the short direction (width) of, for example, 2 mm and a thickness that is, for example, no less than 0.2 mm and is less than a thickness that makes a distance between the electrode films 206 and 238 be a distance that makes it impossible to provide an intended function as an electrochromic element. A thickness of each of the metal thin films 216 and 246 is a thickness that provides a resistance value that is sufficiently low for the metal thin film 216 or 246 to function as a bus bar for the electrode film 206 or 238, and is set to, for example, no less than 1000 angstrom (=100 nm).

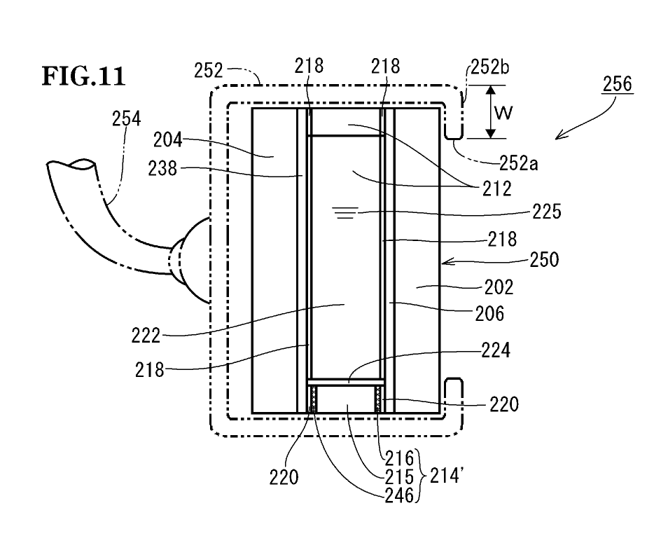

As illustrated in FIG. 11, both surfaces of the spacer 212 are bonded to the respective substrates 202 and 204 via an insulating adhesive 218. A back surface of the spacer 214′ is bonded to the substrate 204 via a conductive adhesive 220 and a front surface of the spacer 214′ is bonded to the substrate 202 via a conductive adhesive 220. Consequently, the substrates 202 and 204 are integrated with the spacers 212 and 214′ interposed therebetween. Here, the substrates 202 and 204 overlap each other without misalignment. In a state in which the substrates 202 and 204 are integrated, the electrode film 206 of the substrate 202 and the metal thin film 216 of the spacer 214′ are conductively connected via the conductive adhesive 220. Also, the electrode and reflection film 238 of the substrate 204 and the metal thin film 246 of the spacer 214′ are conductively connected via the conductive adhesive 220. Also, in the integrated state, a chamber 222 is formed on the inner peripheral side surrounded by the spacers 212 and 214′ between the substrates 202 and 204. The chamber 222 is filled with a liquid electrochromic electrolyte 225 from, for example, a gap 224 between the spacers 212 and 214′. The gap 224 is sealed by, e.g., an adhesive after the filling of the electrochromic electrolyte 225, whereby the chamber 222 is shut off from external air.

As illustrated in FIG. 9, the spacer 214′ is formed to be longer in the long direction than the substrates 202 and 204, whereby an end of the spacer 214′ projects outside of the area between the facing surfaces of the substrates 202 and 204 and thereby forms a projection 214a′. A part 216a of the metal thin film 216 formed on the projection 214a′ provides a terminal disposed so as to be exposed outside of the area between the substrates 202 and 204 in order to connect the electrode film 206 to an external circuit. A part 246a of the metal thin film 246 formed on the projection 214a′ provides a terminal disposed so as to be exposed outside of the area between the substrates 202 and 204 in order to connect the electrode film 238 to the external circuit. An outer peripheral edge of each of the spacers 212 and 214′ overlaps outer peripheral edges of the substrates 202 and 204 except a position of the projection 214a′. Short clip electrodes 226 and 248 are each attached to the projection 214a′ so as to pinch the projection 214a′.

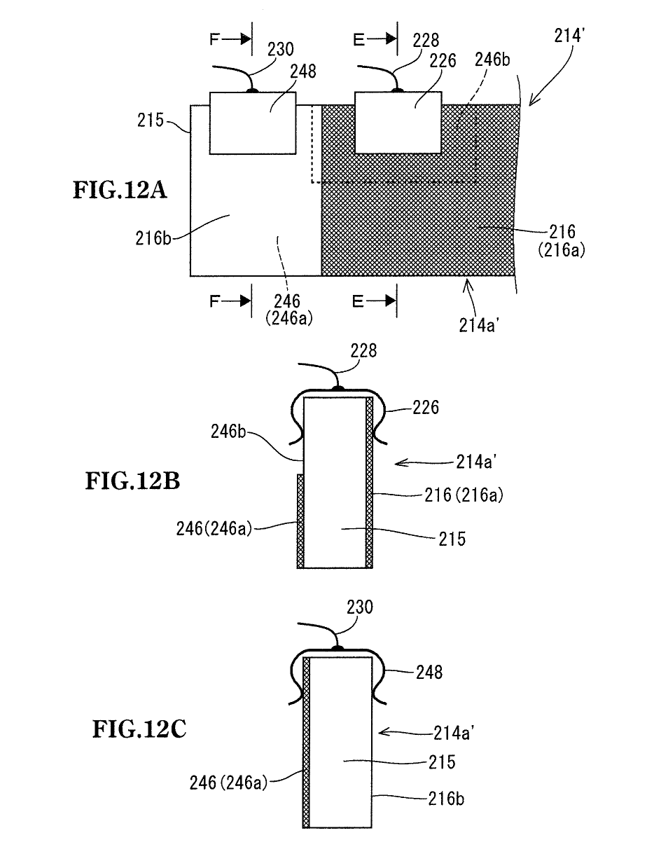

As illustrated as an enlargement in FIG. 12, the metal thin films 216 and 246 are partially cut on the projection 214a′ at respective positions shifted from each other in the long direction of the spacer 214′, whereby cuts 216b and 246b are formed. The clip electrode 226 is attached to a position where the cut 246b is formed, and the clip electrode 248 is attached to a position where the cut 216b is formed. Consequently, the clip electrode 226 is conductively connected to the terminal 216a and is not conductively connected to the terminal 246a. Also, the clip electrode 248 is conductively connected to the terminal 246a and is not conductively connected to the terminal 216a. Consequently, the clip electrode 226 is conductively connected to the electrode film 206 via the metal thin film 216 and the conductive adhesive 220 from the terminal 216a. Also, the clip electrode 248 is conductively connected to the electrode and reflection film 238 via the metal thin film 246 and the conductive adhesive 220 from the terminal 246a. Lead wires 228 and 230 are connected to the respective clip electrodes 226 and 248. The lead wires 228 and 230 are connected between positive and negative electrodes of a direct-current power supply in the external circuit (not illustrated except the lead wires 228 and 230). As with Embodiment 2, upon a switch of the external circuit being turned on to supply a direct-current voltage between the lead wires 228 and 230, the inner mirror 256 enters an anti-glare state, and upon the switch being turned off to short-circuit the lead wires 228 and 230, the inner mirror 256 enters a non-anti-glare state.

As with Embodiment 2, a mirror body 250 is housed and held in a housing (cover) 252 and hung from a ceiling of a front portion of the interior of the vehicle via a stay 254 as illustrated in FIGS. 9 and 11.

As illustrated in FIGS. 9 and 11, an opening 252a that exposes a reflective surface of the inner mirror 256 is formed in a front surface of the housing 252. An edge width W of a front surface edge 252b of the housing 252 is large at a left side for covering the projection 214a′, the clip electrodes 226 and 248 and the lead wires 228 and 230 in addition to the spacer 212, but can be made small at each of an upper side, a lower side and a right side because the edge width W at each of the upper side, the lower side and the right side only needs to have a size sufficient to cover the spacers 212 and 214′. Therefore, as with Embodiment 2, the edge width W can be made smaller, in particular, at the upper side and the lower side, compared to those of the conventional devices illustrated in FIGS. 16, 17 and 18.

### Embodiment 4

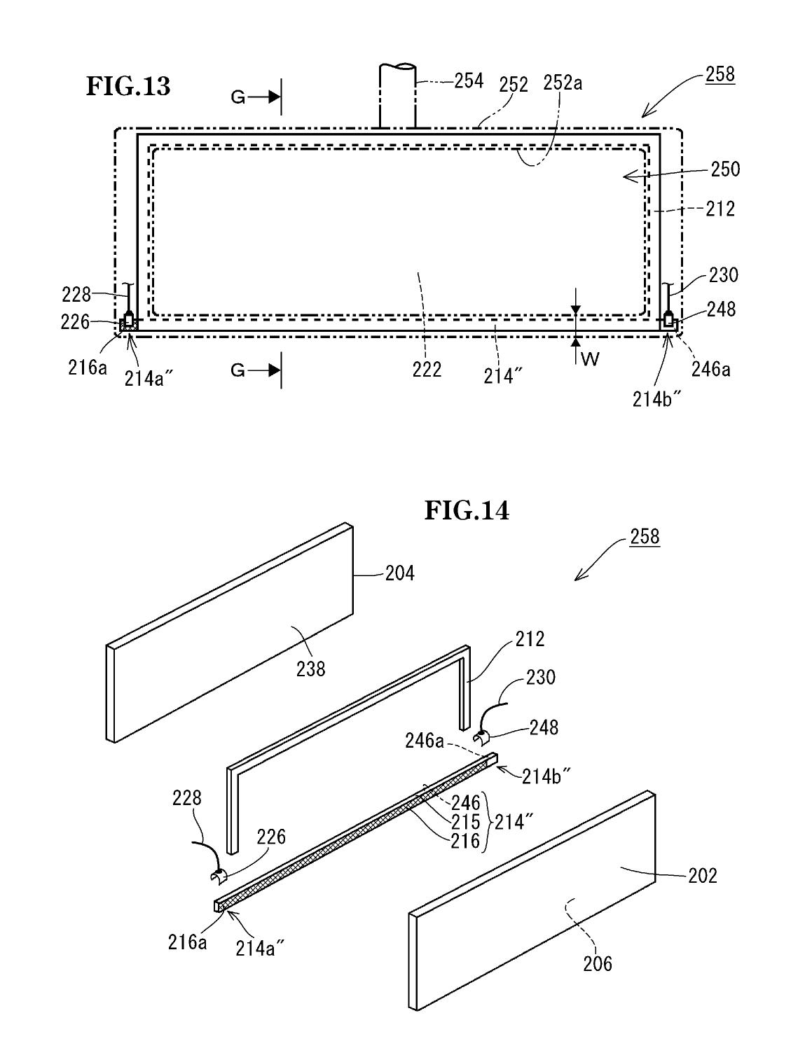

FIGS. 13 to 15 illustrate Embodiment 4 of the present invention. In this embodiment, an electronic device according to the present invention is configured as an electrochromic vehicle inner mirror. Here, the structure of Embodiment 3 is altered in such a manner that projections 214a″ and 214b″ to which respective clip electrodes 226 and 248 are attached are separately formed on the left side and the right side of the inner mirror 258, respectively. The rest of the structure is the same as that of Embodiment 3. For parts corresponding to those of Embodiment 3, reference numerals that are the same as those of Embodiment 3 are used.

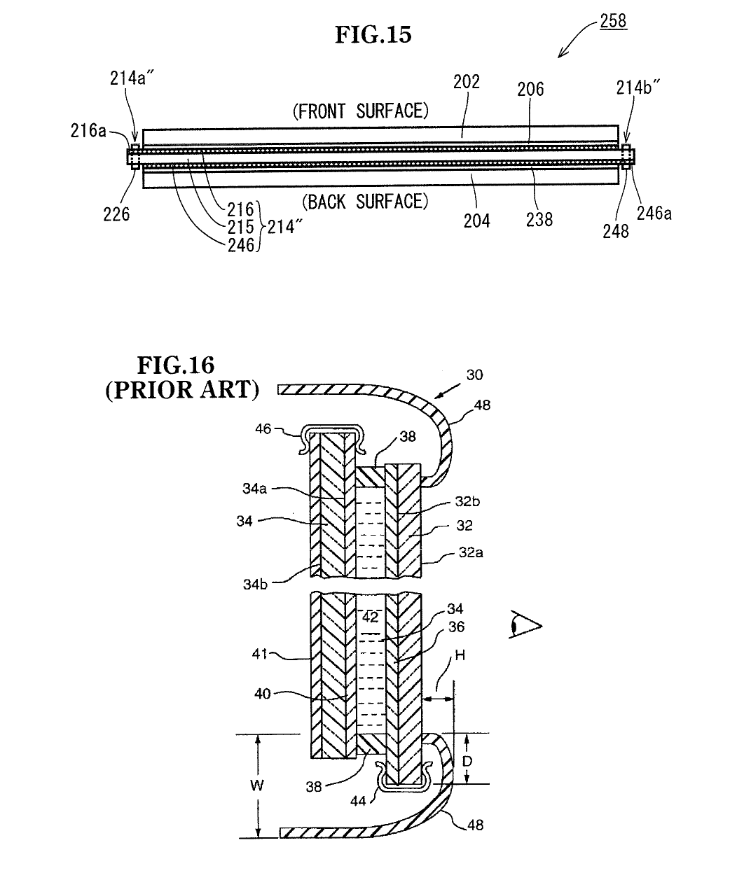

The metal thin film-provided spacer 214″ disposed on the lower sides of the substrates 202 and 204 is different from the spacer 214′ of Embodiment 3 only in terms of regions in which metal thin films 216 and 246 are formed (that is, regions in which cuts in the metal thin films 216 and 246 are formed). In other words, as illustrated in the bottom view in FIG. 15, the metal thin film 216 is formed on an entire front surface except a region at a right end of an insulating plate material 215, and the metal thin film 246 is formed on an entire back surface except a region at a left end of the insulating plate material 215. The spacer 214″ is formed to be longer in a long direction than the substrates 202 and 204, and both ends of the spacer 214″ project outside from an area between facing surfaces of the substrates 202 and 204 and thereby form respective projections 214a″ and 214b″. On the projection 214a″ on the left side, the metal thin film 216 is formed, but the metal thin film 246 is not formed. On the projection 214b″ on the right side, the metal thin film 246 is formed, but the metal thin film 216 is not formed. A part 216a of the metal thin film 216 formed on the projection 214a″ provides a terminal disposed so as to be exposed outside of the area between the substrates 202 and 204 in order to connect an electrode film 206 to an external circuit. A part 246a of the metal thin film 246 formed on the projection 214b″ provides a terminal disposed outside of the area between the substrates 202 and 204 in order to connect an electrode film 206 to the external circuit. A short clip electrode 226 is attached to the projection 214a″ so as to pinch the projection 214a″. A short clip electrode 248 is attached to the projection 214b″ so as to pinch the projection 214b″. Consequently, the clip electrode 226 is conductively connected to the terminal 216a, and the clip electrode 248 is conductively connected to the terminal 246a. Consequently, the clip electrode 226 is conductively connected to the electrode film 206 via the metal thin film 216 and a conductive adhesive 220 from the terminal 216a. Also, the clip electrode 248 is conductively connected to the electrode and reflection film 238 via the metal thin film 246 and a conductive adhesive 220 from the terminal 246a. Lead wires 228 and 230 are connected to the respective clip electrodes 226 and 248. The lead wires 228 and 230 are connected between positive and negative electrodes of a direct-current power supply in the external circuit (not illustrated except the lead wires 228 and 230). As with Embodiment 3, upon a switch of the external circuit being turned on to supply a direct-current voltage between the lead wires 228 and 230, an inner mirror 258 enters an anti-glare state, and upon the switch being turned off to short-circuit the lead wires 228 and 230, the inner mirror 258 enters a non-anti-glare state.

As with Embodiment 3, a mirror body 250 is housed and held in a housing (cover) 252 and hung from a ceiling of a front portion of the interior of the vehicle via a stay 254 as illustrated in FIG. 13 (cross-section on arrow G-G in FIG. 13 is the same as FIG. 11 in Embodiment 3).

As illustrated in FIG. 13, an opening 252a that exposes a reflective surface of the inner mirror 258 is formed in a front surface of the housing 252. An edge width W of a front surface edge 252b of the housing 252 is large at a left side and a right side for covering the projections 214a″ and 214b″, the clip electrodes 226 and 248 and the lead wires 228 and 230 in addition to the spacer 212, but can be made small at each of an upper side and a lower side because the edge width W at each of the upper side and the lower side only needs to have a size sufficient to cover the spacers 212 and 214″, and thus, as with Embodiment 3, the edge width W at each of the upper side and the lower side can be made smaller compared to those of the conventional devices illustrated in FIGS. 16, 17 and 18. Since the upper side and the lower side are longer than the left side and the right side, the ability to reduce the edge width W at the upper side and the lower side provides a large effect in terms of design.

While Embodiment 1 has been described above in terms of a case where the present invention is configured as a transmissive electronic device, Embodiment 1 can be modified as configured, for example, as a reflective electronic device by replacing the electrode film 208 with an electrode and reflection film. Also, while each of Embodiments 2 to 4 has been described in terms of a case where the present invention is configured as a reflective electronic device, each of Embodiments 2 to 4 can be modified as configured as a transmissive electronic device by forming the substrate 204 using a transparent substrate and replacing the electrode and reflection film 238 with a transparent electrode film. Also, while each of the embodiments has been described above in terms of a case where the present invention has been applied to an electrochromic device or a liquid-crystal device, the present invention can be applied also to any of other electronic devices having the configuration stated in the preamble of claim 1 (for example, electronic papers and dye-sensitized solar cells).

### REFERENCE SIGNS LIST

200, 200′ . . . electronic device, 202 . . . first substrate (transparent substrate), 204 . . . second substrate (transparent substrate or substrate), 204a . . . part of second substrate that projects outside, 206 . . . first electrode film (transparent electrode film), 208 . . . second electrode film, 208a . . . part of second electrode film formed in region of second substrate that projects outward (second terminal), 212, 242, 244 . . . spacer, 214 . . . first metal thin film-provided spacer, 214a, 214a′, 214a″ . . . first projection, 215, 244 . . . insulating plate material, 216 . . . first metal thin film, 216a . . . part of first metal thin film formed on first projection (first terminal), 218 . . . insulating adhesive, 220 . . . conductive adhesive, 222 . . . chamber, 225 . . . functional substance or electrochromic electrolyte, 226, 248 . . . clip electrode, 228, 230 . . . lead wire, 234, 256, 258 . . . electronic device (electrochromic vehicle inner mirror), 238 . . . second electrode film (electrode and reflection film), 246a . . . second terminal, 246 . . . second metal thin film, 240 . . . second metal thin film-provided spacer, 240a, 214b″ . . . second projection, 246a . . . part of second metal thin film formed on first projection or part of second metal thin film formed on second projection (second terminal)

1. An electronic device comprising:
first and second substrates disposed facing each other;
first and second electrode films formed on facing surfaces of the first and second substrates, respectively;
first and second terminals disposed so as to be exposed outside of an area between the first and second substrates in order to each connect the first and second electrode films with an external circuit disposed outside of the area between the first and second substrates;
a spacer inserted in a peripheral edge of the area between the facing surfaces of the first and second substrates and joined between the facing surfaces, an inner peripheral side of the inserted spacer forming a chamber between the facing surfaces of the first and second substrates; and
a functional substance contained in the chamber,
wherein the spacer includes a first metal thin film-provided spacer having a part being disposed along at least a partial region of an entire length of the peripheral edge between the first and second substrates, the part of the first metal thin film-provided spacer has a first metal thin film formed on at least one surface of an insulating plate material;
wherein the surface of the first substrate with the first electrode film formed thereon and the surface of the first metal thin film-provided spacer with the first metal thin film formed thereon are conductively joined to each other, whereby the first metal thin film is conductively connected to the first electrode film and is not conductively connected to the second electrode film; and
wherein the first electrode film is conductively connected to the first terminal via the first metal thin film.

2. The electronic device according to claim 1,
wherein the first metal thin film-provided spacer includes a first projection projecting outside of the area between the facing surfaces of the first and second substrates from a position in a part in an extension direction of the first metal thin film-provided spacer; and
wherein a part of the first metal thin film formed on the first projection provides the first terminal.

3. The electronic device according to claim 1, wherein the second substrate includes a region projecting outward relative to the first substrate on an opposite side of a region in which the first metal thin film-provided spacer is disposed in the entire length of the peripheral edge between the first and second substrates, and a part of the second electrode film formed on the region of the second substrate, the region projecting outward, provides the second terminal.

4. The electronic device according to claim 2, wherein the second substrate includes a region projecting outward relative to the first substrate on an opposite side of a region in which the first metal thin film-provided spacer is disposed in the entire length of the peripheral edge between the first and second substrates, and a part of the second electrode film formed on the region of the second substrate, the region projecting outward, provides the second terminal.

5. The electronic device according to claim 1,
wherein the spacer includes a second metal thin film-provided spacer having a part being disposed in a region on an opposite side of the region in which the first metal thin film-provided spacer is disposed in the entire length of the peripheral edge between the first and second substrates, the part of the second metal thin film-provided spacer has a second metal thin film formed on one surface of an insulating plate material;
wherein the surface of the second substrate with the second electrode film formed thereon and the surface of the second metal thin film-provided spacer with the second metal thin film formed thereon are conductively joined to each other, whereby the second metal thin film is conductively connected to the second electrode film and not conductively connected to the first electrode film; and
wherein the second electrode film is conductively connected to the second terminal via the second metal thin film.

6. The electronic device according to claim 2,
wherein the spacer includes a second metal thin film-provided spacer having a part being disposed in a region on an opposite side of the region in which the first metal thin film-provided spacer is disposed in the entire length of the peripheral edge between the first and second substrates, the part of the second metal thin film-provided spacer has a second metal thin film formed on one surface of an insulating plate material;
wherein the surface of the second substrate with the second electrode film formed thereon and the surface of the second metal thin film-provided spacer with the second metal thin film formed thereon are conductively joined to each other, whereby the second metal thin film is conductively connected to the second electrode film and not conductively connected to the first electrode film; and
wherein the second electrode film is conductively connected to the second terminal via the second metal thin film.

7. The electronic device according to claim 5,
wherein the second metal thin film-provided spacer includes a second projection projecting outside of the area between the facing surfaces of the first and second substrates from a position in a part in an extension direction of the second metal thin film-provided spacer; and
wherein a part of the second metal thin film formed on the second projection provides the second terminal.

8. The electronic device according to claim 6,
wherein the second metal thin film-provided spacer includes a second projection projecting outside of the area between the facing surfaces of the first and second substrates from a position in a part in an extension direction of the second metal thin film-provided spacer; and
wherein a part of the second metal thin film formed on the second projection provides the second terminal.

9. The electronic device according to claim 1,
wherein the first metal thin film-provided spacer includes a second metal thin film formed on a back surface of the insulating plate material;
wherein the surface of the second substrate with the second electrode film formed thereon and the surface of the first metal thin film-provided spacer with the second metal thin film formed thereon are conductively joined to each other, whereby the second metal thin film is conductively connected to the second electrode film and is not conductively connected to the first electrode film; and
wherein the second electrode film is conductively connected to the second terminal via the second metal thin film.

10. The electronic device according to claim 9,
wherein the first metal thin film-provided spacer includes a first projection projecting outside of the area between the facing surfaces of the first and second substrates from a position in a part in an extension direction of the first metal thin film-provided spacer;
wherein a part of the first metal thin film formed on the first projection provides the first terminal; and
wherein a part of the second metal thin film formed on the first projection provides the second terminal.

11. The electronic device according to claim 9,
wherein the first metal thin film-provided spacer includes a first projection projecting outside of the area between the facing surfaces of the first and second substrates from a position in a part in an extension direction of the first metal thin film-provided spacer, and a second projection projecting outside of the area between the facing surfaces of the first and second substrates from a position in another part in the extension direction of the first metal thin film-provided spacer;
wherein a part of the first metal thin film formed on the first projection provides the first terminal; and
wherein a part of the second metal thin film formed on the second projection provides the second terminal.

12. The electronic device according to claim 1, wherein the insulating plate material of the first metal thin film-provided spacer includes a material that is any of a glass plate, a ceramic plate and a plastic plate.

13. The electronic device according to claim 1, wherein the insulating plate material of the first metal thin film-provided spacer has a thickness of no less than 0.2 mm.

14. The electronic device according to claim 1, wherein the first metal thin film includes a metal material that is any of Cr, Al, Ag and Ni.

15. The electronic device according to claim 1, wherein the first metal thin film-provided spacer is disposed on a side along long directions of the first and second substrates.

16. The electronic device according to claim 2, wherein a clip electrode is attached to the first projection so as to pinch the first projection and a lead wire is connected to the clip electrode, whereby the lead wire is conductively connected to the first electrode film formed on the projection via the clip electrode.

17. The electronic device according to claim 1, wherein an outer peripheral edge of the first metal thin film-provided spacer is disposed so as to overlap an outer peripheral edge of each of the substrates.

18. The electronic device according to claim 1, wherein the surface of the first substrate with the first electrode film formed thereon and the surface of the first metal thin film-provided spacer with the first metal thin film formed thereon are conductively joined to each other via bonding using a conductive adhesive.

19. The electronic device according to claim 18, wherein all surfaces of the spacer other than the surface subjected to the bonding using the conductive adhesive are joined to the first and second substrates via bonding using an insulating adhesive.

20. The electronic device according to claim 1,
wherein at least one of the first and second substrates is a transparent substrate;
wherein at least an electrode film formed on the transparent substrate from among the first and second electrode films is a transparent electrode film; and
wherein the functional substance is a substance having an optical characteristic that varies depending on a voltage or a current supplied between the first and second electrode films.

21. A metal thin film-provided spacer to be used as the spacer in an electronic device, the electronic device including first and second substrates disposed facing each other, first and second electrode films formed on facing surfaces of the first and second substrates, respectively, the spacer inserted in a peripheral edge of an area between the facing surfaces of the first and second substrates and joined between the facing surfaces, an inner peripheral side of the inserted spacer forming a chamber between the facing surfaces of the first and second substrates, and a functional substance contained in the chamber,
wherein the metal thin film-provided spacer has a structure in which a metal thin film is formed on at least one surface of an insulating plate material.
